(19) United States
(12) Patent Application Publication
(10) Pub. No.: US 2026/0141945 A1
(43) Pub. Date: May 21, 2026

(54) SELF-CALIBRATION IN A MEMORY DEVICE

(71) Applicant: Micron Technology, Inc., Boise, ID (US)

(72) Inventors: Sompur M. Shivakumar, Columbia, SC (US); Jennifer E. Taylor, Boise, ID (US)

(21) Appl. No.: 19/346,091

(22) Filed: Sep. 30, 2025

Related U.S. Application Data
(60) Provisional application No. 63/722,931, filed on Nov. 20, 2024.

(51) Int. Cl. G11C 11/4076; G11C 29/50

(52) U.S. Cl. CPC G11C 11/4076; G11C 29/50012

(57) ABSTRACT

Systems and methods include a memory device that includes a memory interface configured to receive a data and a clock from a host device. The memory device also includes alignment circuitry configured to sample the data based at least in part on the clock. The alignment circuitry also is configured to count a first number of samples of the data sampled as a current symbol and to count a second number of samples sampled as a previous symbol. The alignment circuitry further sets an amount of delay based on a comparison of the first number and the second number and generates a data strobe as a locally generated data strobe by adding or subtracting the set amount of delay to the clock.

### CROSS-REFERENCE TO RELATED APPLICATIONS

This application claims priority to U.S. Provisional Application No. 63/722,931, filed November 20, 2024, which is incorporated by reference herein in its entirety.

### BACKGROUND

### FIELD OF THE INVENTION

Embodiments of the present disclosure relate generally to the field of semiconductor memory devices. More specifically, embodiments of the present disclosure relate to a self-calibration and tracking in a dynamic random access memory (DRAM) device.

### DESCRIPTION OF THE RELATED ART

The operational rate of memory devices, including the data rate of a memory device, has been increasing over time. As a side effect of the increase in speed of a memory device, data errors due to distortion may increase. For example, inter-symbol interference between transmitted data whereby previously received data influences the currently received data may occur (e.g., previously received data affects and interferes with subsequently received data). One manner to correct for this interference is through the use of a decision feedback equalizer (DFE) circuit, which may be programmed to offset (i.e., undo, mitigate, or offset) the effect of the channel on the transmitted data.

Additionally, correcting distortions in the transmitted signals continues to be important. One way to correct the distortions may be to use link training and subsequent re-training where the host device (e.g., processor) trains the link of double-data rate (DDR) interfaces between the DRAM devices and the host device. This link training/re-training includes the host device sending/receiving signals through the DDR interfaces while programming adjustments of interface-related parameters. However, link training time and subsequent retraining for the DDR interfaces of these DRAM devices may be relatively lengthy and negatively impact a user experience or may be complicated due to orthogonal receiver parameters.

### BRIEF DESCRIPTION OF THE DRAWINGS

Various aspects of this disclosure may better be understood upon reading the following detailed description and upon reference to the drawings in which:

FIG. 1 is a simplified block diagram illustrating certain features of a memory device that includes alignment circuitry to align a data strobe to a center of a data eye, according to an embodiment of the present disclosure;

FIG. 2 illustrates a block diagram of the adjustment circuitry of the memory device of FIG. 1 that includes edge sampler circuitry, error averager circuitry, and phase generator circuitry according to an embodiment of the present disclosure;

FIG. 3 is a graph showing waveforms corresponding to the data and clock. The clock is the edge clock used by the edge sampler circuitry of FIG. 2, according to an embodiment of the present disclosure;

FIG. 4 shows a block diagram of the error averager circuitry of FIG. 2, according to an embodiment of the present disclosure;

FIG. 5 is a block diagram of the phase generator circuitry of FIG. 2, according to an embodiment of the present disclosure; and

FIG. 6 is a graph showing a timing diagram of values in the adjustment circuitry of FIG. 1 showing a previous delay value, a delay value, and an update value indicating whether to increment, decrement, or hold the delay value from the previous delay value, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As previously noted, corrections for distortions of bits between a host device (e.g., processor) and a memory device may be performed by link training/re-training. For instance, such distortions may be related to process, voltage, and temperature (PVT) variations where performance changes with PVT changes between situations and/or devices. However, such link training/re-training may be lengthy to complete and may negatively impact the use of the memory device. To at least partially mitigate negative impact, the memory device may be used to autonomously train the memory interface and/or autonomously adjust circuit parameters following a training to maintain an interface margin during operation of the memory device. As discussed below, this autonomous training and/or adjustment may factor in memory environment-specific complications, such as single-ended signaling, bursty data transmission (including related rapid power up and/or power down), relatively poor transistor performance, bi-directional pins, and/or other situations that may not be applicable to non-memory device calibration/training.

Furthermore, as discussed below, to compensate for such distortions, the memory device may include alignment circuitry that continuously aligns a data strobe (e.g., DQ strobe or DQS) within the middle of the data eye where PVT variations may cause the data strobe to become misaligned with the center of the data eye even if originally aligned during boot-up or reset of the memory device. This use of circuitry to continuously align the data strobe with the middle of the data eye may enable the memory device to keep the data strobe near the middle of the data eye throughout parameter changes (e.g., PVT variations) that may impact operation. The continuous alignment of the data strobe to the data eye may be performed by generating the data strobe with an amount of delay that puts an edge of a pulse of the strobe in the middle of the data eye to ensure high fidelity of data capture.

Furthermore, by aligning the DQ to the middle of the eye rather than configuring a receiver to provde a wider eye may provide a power efficient and/or more consistent solution than applying adjustments to the receiver. Applying adjustments to the receiver may be more complicated due to receivers applying many adjustments concurrently that may not be orthogonal to each other. These non-orthogonal adjustments may still impact each other and/or be more difficult to predict/implement than aligning the data strobe to an eye of the data (e.g., DQ).

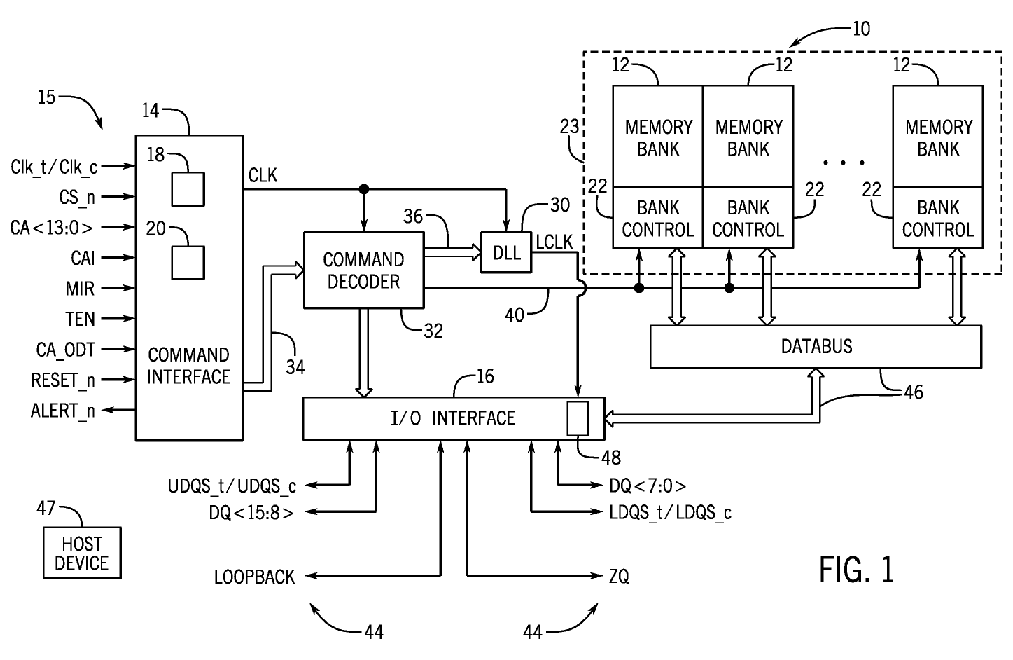

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random-access memory (DDR5 SDRAM) device. Various features of DDR5 SDRAM allow for reduced power consumption, more bandwidth and more storage capacity compared to prior generations of DDR SDRAM.

The memory device 10 may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization, and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over a data bus 46 that includes multiple bi-directional data connections. Data I/O signals, generally referred to as DQ signals, are generally transmitted and received in one or more bi-directional data connections. For certain memory devices, such as a DDR5 SDRAM memory device, the I/O signals may be divided into upper and lower bytes. For instance, for an x16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance. In some embodiments as discussed below, the DQS may be internally generated from a clock received at the memory device 10 from the host device 47. In some such embodiments the DQS pins may be omitted from the memory device 10.

An impedance (ZQ) calibration signal may also be provided to the memory device 10 through the I/O interface 16. The ZQ calibration signal may be provided to a reference pin and used to tune output drivers and ODT values by adjusting pull-up and pull-down resistors of the memory device 10 across changes in process, voltage, and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory system 10. Accordingly, it should be understood that the block diagram of FIG. 1 is only provided to highlight certain functional features of the memory device 10 to aid in the subsequent detailed description.

In some embodiments, the memory device 10 may be coupled to a host device 47. The host device 47 may include a processor, such as a central processing unit (CPU), a graphics processing unit (GPU), another microprocessor, a programmable logic device, and/or any other suitable processor that controls processing of system functions and requests. Further, any host device/processor may include multiple processing units.

The host device 47 may operate to transfer data to the memory device 10 for storage and may read data from the memory device 10 to perform various operations. Accordingly, to facilitate these data transmissions, in some embodiments, the I/O interface 16 may include adjustment circuitry 48 that operates to receive and transmit align data strobe (e.g., DQS) signals to the middle of eyes of data signals (e.g., DQ signals).

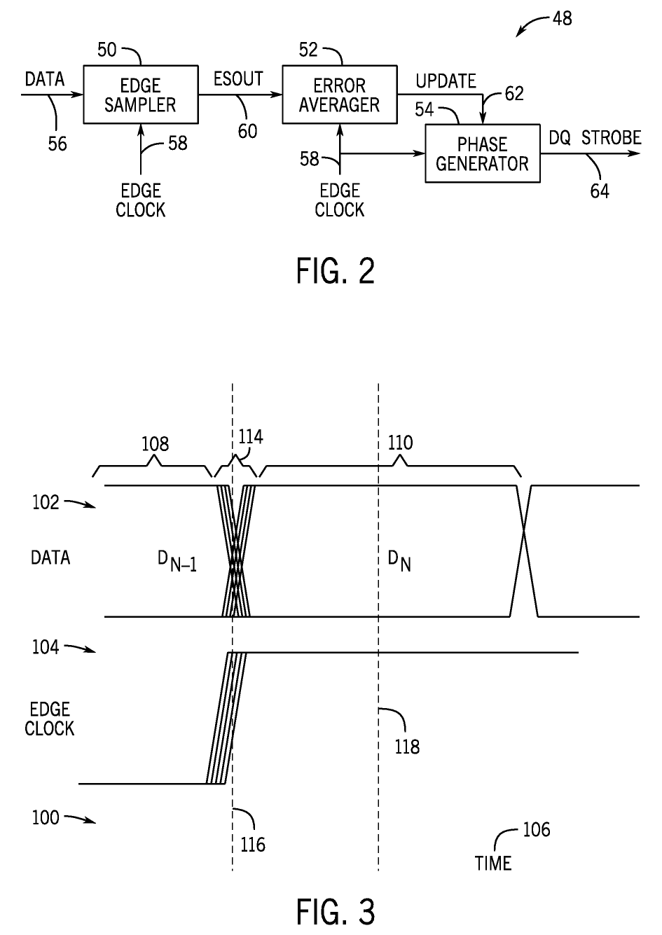

FIG. 2 illustrates a block diagram of an embodiment of the adjustment circuitry 48 of the memory device 10. As illustrated, the adjustment circuitry 48 includes edge sampler circuitry 50, error averager circuitry 52, and phase generator circuitry 54.

The edge sampler circuitry 50 may be circuitry that samples incoming data 56. The data 56 may be any data received at the memory device 10. For instance, the data 56 may be any DQ signal received at the memory device 10. The edge sampler circuitry 50 receives an edge clock 58.

The edge clock 58 may be received from the host device 47 already edge-aligned to the data 56. In some embodiments, the edge clock 58 may be derived from a center-aligned clock received from the host device 47. Regardless of how the edge clock 58 is aligned to the data 56, it may be aligned using a delay locked loop (DLL) that is locked during initial training of the memory interface during link training during a boot up or reset of the memory device 10.

The edge sampler circuitry 50 may sample the data 56 using the edge clock 58 that is aligned to the edge of the data 56. As such, the edge sampler circuitry 50 may be any circuitry that may be suitable to capture/sample the data 56 using a clock (e.g., the edge clock 58). For instance, the edge sampler circuitry 50 may be embodied using a simple flip-flop or latch that receives the data 56 at a data input and the edge clock 58 at a clock input. In other embodiments, other circuitry may be used to sample the data 56 periodically. For instance, the capturing/sampling may be implemented using floating gate transistors, capacitors, and/or any other circuitry suitable for capturing, sampling, or storing the data 56 at a specific period of time based on the edge clock 58.

The edge clock 58 may be a clock that is a fraction (e.g., 1/4) of a received clock (e.g., Clk_t/Clk_c). The adjustment circuitry 48 is illustrated with a single instance of the edge sampler circuitry 50, but in certain embodiments, there may be a corresponding edge sampler circuitry 50 for each clock (e.g., 4 clocks) when the external clock is phase divided into multiple clocks for interleaving. Thus, in memory devices that divide the clock into four phases, such memory devices may include four edge sampler circuitries 50. The edge sample circuitry 50 may output an edge sample out (ESout) 60 as an indicator of whether a previous bit or a current bit has been captured using the edge clock 58.

The error averager circuitry 52 receives the ESout 60 from one or more edge sampler circuitries 50 and processes the ESout 60 to issue an update signal 62 that indicates whether an amount of delay should be increased, decreased, or remain unchanged. As discussed below, the error averager circuitry 52 averages the errors across a time period to try to balance the number of captures of the previous bit and the current bit. The period of time over which the “error” is averaged may be configurable. For instance, the duration may be modified by the host device 47 using one or more memory registers.

The phase generator 54 receives the update signal 62 from the error averager circuitry 52. The phase generator 54 also receives the edge clock 58. The phase generator 54 decodes the update signal 62 to apply an amount of delay to be used. The phase generator 54 then adds or subtracts the amount of delay to the edge clock 58 to generate a DQ strobe 64. The edges of the DQ strobe 64 may be aligned to the center of the eye of the corresponding DQ. Since this DQ strobe 64 continuously follows any variations (e.g., PVT variations) in the memory device and the platform/host, the DQ strobe 64 may keep its edge aligned at the middle of the eye of the data 56 regardless of such fluctuations.

Since the data 56 is captured using the edge clock 58 that is aligned to its edge, any deviation/jitter in either direction of time is about as likely to be decided as a current bit as it is to be decided as a previous bit. FIG. 3 is a graph 100 showing embodiments of lines 102 corresponding to the data 56 and lines 104 corresponding to the edge clock 58. The graph 100 shows different locations of the data units of the data 56 and pulses of the edge clock 58 may vary in time 106.

As illustrated, a previous data (Dn-1) 108 corresponds to an earlier symbol in the data 56 while current data (Dn) 110 corresponds to a current symbol in the data 56. However, fluctuations in the data 56 and/or the edge clock 58 may cause uncertainty in a fluctuations region 114. The data 56 and the edge clock 58 may both be received from the host device 47 or derived from the host device 47, but they may be in phase or out of phase with each other causing phase fluctuations. The phase fluctuations may be related to jitter, PVT variations, crosstalk, and/or due to electronic properties of the memory device 10, the host device 47, and/or the interface between the memory device 10 and the host device 47 that may impact the data 56 and the edge clock 58 differently. These phase fluctuations may cause uncertainty on whether sampling will result in the data from Dn-1 (data from previous sampling period) 108 or data from Dn (data from current sampling period)110 being sampled with the clock edge of the edge clock 58 depending on whether the edge clock leads or lags the data at the moment of sampling. Thus, by sampling at time 116 rather than in the center of an eye of the data (e.g., time 118), the edge sampler circuitry 50 may be setup to approximately as likely to sample Dn-1108 as Dn 110 and output such sampling as the ESOut 60.

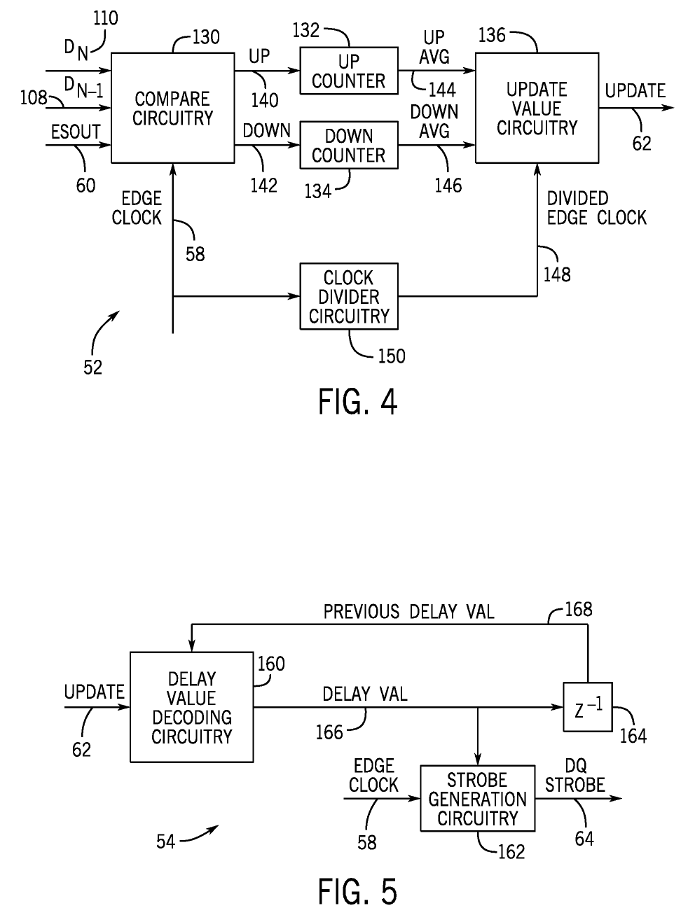

FIG. 4 shows a block diagram of an embodiment of the error averager circuitry 52 that may be used in the alignment circuitry 48. The error averager circuitry 52 includes compare circuitry 130, an up counter 132, a down counter 134, and update value circuitry 136.

The compare circuitry 130 receives Dn-1108, Dn 110, and the ESout 60. The Dn 110 and the Dn-1108 used by the compare circuitry 130 may be derived closer to the center of the data eye (e.g., at time 118) to ensure that Dn-1108 and Dn 110 are properly sampled. The compare circuitry 130 then compares the properly sampled Dn-1108 and Dn 110 to the ESout 60 that is sampled using the edge clock. When the ESout 60 matches Dn 110 while Dn-1108 is not the same as Dn 110, the compare circuitry 130 outputs a value (e.g., logic high or 1) on an up signal 140 and an inverse/complementary value (e.g., logic low or 0) on a down signal 142. The compare circuitry 130 may send the value on the up signal 140 when the Dn-1108 is not the same as Dn 110 since it may be impossible to distinguish whether the ESout 60 corresponds to the Dn-1108 or corresponds to the Dn 110 since they both carry the same value. Thus, when Dn-1108 and the Dn 110 are the same, the compare circuitry 130 keeps both the up signal 140 and the down signal 142 at the same inverse value.

When the ESout 60 does not match Dn 110 while Dn-1108 is not the same as Dn 110, the compare circuitry 130 outputs the value on the down signal 142 and the inverse value on the down signal 142. If ESout 60 does not match either Dn-1108 or Dn 110 in addition or alternative to Dn-1108 or Dn 110 matching each other, the compare circuitry 130 keeps both the up signal 140 and the down signal 142 at the same inverse value.

The up counter 132 increments an up count with each value transmitted from the compare circuitry 130 on the up signal 140. Likewise, the down counter 134 increments a down count with each value transmitted from the compare circuitry 130 on the down signal 142. The cumulative up count (UpAvg) 144 is transmitted from the up counter 132 to the update value circuitry 136. Likewise, the cumulative down count (DownAvg) 146 is transmitted from the down counter 134 to the update value circuitry 136.

The update value circuitry 136 may examine the UpAvg 144 and the DownAvg 146 every Nth clock cycle using a divided edge clock 148. To generate the divided edge clock 148, the error average circuitry 52 includes clock divider circuitry 150 that receives the edge clock 58 and divides it by N. In some embodiments, the clock divider circuitry 150 may be programmable such that N may be changed by the host device 47 and/or the memory device 10. For instance, the clock divider circuitry 150 may include a counter that outputs a value when N cycles have been counted. Alternatively, the clock divider circuitry 150 may include any other suitable circuitry that may count N cycles before causing a pulse on the divided edge clock 148.

When the update value circuitry 136 receives a pulse on the divided edge clock 148, the update value circuitry 136 may determine whether to output an increment, decrement, or hold value on the update signal 62. When the UpAvg 144 is greater than the DownAvg 146, ESout 60 is more frequently matched to the Dn 110 than to the Dn-1108 indicating that the edge of the edge clock 58 may tend to occur after the edge of the data 56. To correct for this tendency, the update value circuitry 136 causes the update signal 62 to have an increment value (e.g., 1 V) to increase the delay to the edge clock 58 in generating the data strobe to compensate for such skew.

When the UpAvg 144 is lesser than the DownAvg 146, ESout 60 is less frequently matched to the Dn 110 than to the Dn-1108 indicating that the edge of the edge clock 58 may tend to occur earlier than the edge of the data 56. To correct this tendency, the update value circuitry 136 causes the update signal 62 to have a decrement value (e.g., -1 V) to decrease the delay to the edge clock 58 in generating the data strobe to compensate for such skew.

When the UpAvg 144 is the same as the DownAvg 146, ESout 60 has been matched equally to the Dn 110 and the Dn-1108 meaning that the edge clock 58 pulses are aligned to the edge of the data and equally likely to be sampled as Dn 110 as to be sampled as Dn-1108. In such situations, the update value circuitry 136 may cause the update signal 62 to have a hold value (e.g., 0 V) that causes the delay to be unchanged.

FIG. 5 is a block diagram of an embodiment of the phase generator circuitry 54 that may be used in the alignment circuitry 48. As illustrated, the phase generator circuitry 54 includes delay value decoding circuity 160, strobe generation circuitry 162, and unit delay circuitry (Z⁻¹) 164. The delay value decoding circuitry 160 receives the update signal 62 from the error averager circuitry 52. The delay value decoding circuitry 160 decodes the update signal to generate a delay value signal (DelayVal) 166 used to instruct the strobe generation circuitry 162 on how much delay to add or subtract to the edge clock 58 in generating the DQ strobe 64. This delay value signal 166 is based on a previous delay value signal (previousDelayVal) 168 that the unit delay circuitry 164 generates by delaying the delay value signal 166 by a sample period (e.g., a clock cycle of the edge clock 58 or of the divided edge clock 148).

When the update signal carries an increment value (e.g., 1 V), the delay value decoding circuitry 160 may output the delay value signal 166 as the previous delay signal 168 plus some increment. This increment may be based on an amount of granularity (e.g., a number of steps) of delay that may be added by the strobe generation circuitry 162. Since the amount of delay is to be less than the symbol time (e.g., 100 picoseconds) of Dn 110 and Dn-1108 to keep from shifting from the beginning of a symbol into a next symbol, the maximum delay added should be less than the symbol time. This maximum delay may be divided by the number of steps/granularity possible in the alignment circuitry 48. If x is the number of steps, the amount of incremented delay may be equal to 1/x * the symbol time (e.g., 100 ps) of Dn 110 and Dn-1108. For instance, if x is 64 and the symbol time is 100 ps, the incremental delay from one increment due to the update signal 62 carrying an increment value would be approximately 1.56 ps. In other words, in such scenarios, the current delay would be around 1.56 ps longer than the previous delay used.

When the update signal 62 indicates a decrement value (e.g., -1 V), the delay value signal 166 carries a value that is less than the previous delay value 168. For instance, the amount of delay may be less by the same amount (e.g., 1.56 ps) than may be added by the increment value on the update signal 62 previously discussed. Alternatively, the amount of added delay in an incrementing of the delay may be longer or shorter than the amount of removed delay in a decrementing of the delay. When the update signal indicates a hold value (e.g., 0 V), the delay value signal 166 remains the same as the previous delay value 168.

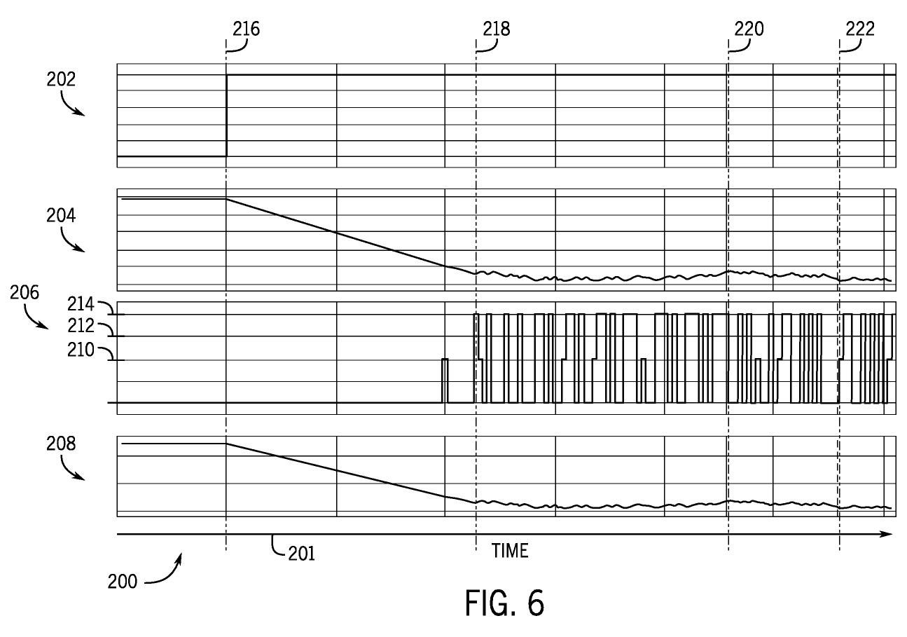

FIG. 6 is a graph 200 showing a timing diagram of values in the adjustment circuitry 48 over time 201. The graph 200 includes sub-graphs 202, 204, 206, and 208. The sub-graph 202 corresponds to an enable signal used to enable adjusting the delay value signal 166 using the adjustment circuitry 48. The sub-graph 204 corresponds to the previous delay value signal 168, the sub-graph 206 corresponds to the update signal 62, and the sub-graph 208 corresponds to the delay value signal 166. The sub-graph 206 shows a decrement value 210 (e.g., -1 V), a hold value 212 (e.g., 0 V), and an increment value 214 (e.g., 1 V) used to denote whether the delay is to increase or decrease relative to a previous delay.

As shown in the sub-graph 202 at time 216, the enable signal is asserted thereby causing the adjustment circuitry 48 to begin adjusting the delay value signal 166 and the previously delay value signal 168. From time 216 to time 218, the update signal 62 almost exclusively carries the decrement value 210 causing the delay value signal 166 and the previously delay value signal 168 to steadily decrease. After time 218, the delay value signal 166 and the previously delay value signal 168 change with the update signal 62 oscillating between the increment value 214, the hold value 212, and the decrement value 210. Between times 220 and 222 and beyond, the delay value signal 166 and the previously delay value signal 168 continue to settle into normal operation continuously adjusting generation of the DQ strobe 64 to compensate for any fluctuations between the data 56 and any clocks (e.g., the edge clock 58).

As previously noted, by continuously adjusting the strobe generation, receivers of the memory device 10 may have better eye width margins in spite of fluctuations (e.g., PVT fluctuations). Furthermore, by internally generating the DQ strobe 64 in the adjustment circuitry 48 of the memory device 10, the memory device 10 may operate at high speeds without explicit DQS pins to receive DQS from the host device 47. The omission of the DQS pins and associated infrastructure will provide power savings that may be used to at least partially compensate for additional power consumption due to inclusion of the adjustment circuitry 48. Moreover, the ability to self-adjust the DQ strobe 64 during normal write patterns may account for crosstalk influences that may not normally be detectable during a checkerboard (ckbd)-type data pattern-based training that may be performed by host devices (e.g., the host device 47). These normal write patterns enable testing of in-phase and out-of-phase crosstalk during normal write patterns of the memory device 10.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A memory device, comprising:
a memory interface configured to receive a data and a clock from a host device; and
alignment circuitry configured to:
sample the data based at least in part on the clock;
count a first number of samples of the data sampled as a current symbol;
count a second number of samples sampled as a previous symbol;
set an amount of delay based on a comparison of the first number and the second number; and
generate a data strobe as a locally generated data strobe by adding the set amount of delay to the clock.

2. The memory device of claim 1, wherein the clock is received from the host device as an edge clock edge aligned to the data.

3. The memory device of claim 1, wherein the clock is received from the host device as a center aligned clock that is aligned to a center of a data eye of the data, and the alignment circuitry is configured to generate, from the clock, an edge clock that is edge-aligned to the data.

4. The memory device of claim 1, comprising a clock divider configured to divide the clock into multiple divided clocks, wherein the alignment circuitry is configured to sample each of the divided clocks to count the first number and the second number.

5. The memory device of claim 1, wherein the memory interface comprises a delay locked loop (DLL) that is configured to lock during link training during a boot up or reset of the memory device.

6. The memory device of claim 1, wherein the alignment circuitry is configured to count the first and second numbers during write operations to track fluctuations of a relationship between the clock and a data eye of the data during the write operations.

7. The memory device of claim 6, wherein the alignment circuitry is configured to change the set amount of delay used to generate the locally generated strobe to compensate for the tracked fluctuations.

8. The memory device of claim 1, wherein the memory interface is configured to use the locally generated data strobe to capture the data from the host device.

9. The memory device of claim 1, wherein the memory interface does not include a data strobe pin to receive the data strobe from the host device but uses the data strobe to capture data from the memory device.

10. The memory device of claim 1, wherein alignment circuitry comprises:
edge sampler circuitry configured to sample the data;
error averager circuitry configured to:
count the first number based on the sampling of the data;
count the second number based on the sampling of the data; and
generate an update signal configured to increment, decrement, or hold the amount of delay based on the first number and the second number; and
phase generator circuitry configured to:
set the amount of delay based on a previous amount of delay and the update signal; and
generate the data strobe based on the set amount of delay.

11. The memory device of claim 1, wherein the set amount of delay is configured to align the data strobe to a center of a data eye of the data.

12. A method, comprising:
receiving, at a semiconductor device, data from a host device;
receiving, at the semiconductor device, a clock from the host device;
sampling, using alignment circuitry of the semiconductor device, the data at an edge of data eyes of the data based on the clock;
tracking, using the alignment circuitry of the semiconductor device, skew between the data and the clock based on whether a sampled symbol corresponds to a current symbol or a previous symbol;
setting, using the alignment circuitry of the semiconductor device, an amount of delay based at least in part on the tracked skew; and
generating, using the alignment circuitry of the semiconductor device, a data strobe using the set amount of delay to align the data strobe to centers of the data eyes of the data.

13. The method of claim 12, wherein the semiconductor device comprises a memory device.

14. The method of claim 12, comprising capturing the data at the semiconductor device using the data strobe.

15. The method of claim 14, wherein the semiconductor device does not receive the data strobe from the host device.

16. A semiconductor device, comprising:
an interface configured to receive a clock and data from another device; and
alignment circuitry configured to receive the clock and the data and comprising:
edge sampler circuitry configured to sample at edges of data eyes of the data based on the clock and generate an output signal that is sampled at a data edge that corresponds to a current data symbol or a previous data symbol;
error averager circuitry configured to receive the output signal and to generate an update signal based at least in part on an accumulation of output signals from the edge sampler circuitry, wherein the update signal indicates whether an amount of delay is to be incremented, decremented, or held; and
phase generator circuitry configured to receive the update signal, set the amount of delay based on the update signal and a previous amount of delay, and add or subtract the amount of delay to the clock to generate a data strobe that is aligned to centers of the data eyes.

17. The semiconductor device of claim 16, wherein the other device comprises a host device, and the clock comprises an edge clock aligned to the edges of the data eyes.

18. The semiconductor device of claim 16, wherein the error averager circuitry comprises compare circuitry configured to:
receive the current data symbol;
receive the previous data symbol;
receive the output signal;
increment an up count when the output signal matches the current data symbol; and
increment a down count when the output signal matches the previous data symbol.

19. The semiconductor device of claim 18, wherein the error averager circuitry comprises update value circuitry configured to:
receive an accumulated up count;
receive an accumulated down count; and
generate the update signal to indicate an incrementing of the amount of delay when the accumulated up count is greater than the accumulated down count, to indicate a decrementing of the amount of delay when the accumulated down count is greater than the accumulated up count, and to indicate a holding of the amount of delay when the accumulated down count is equal to the accumulated up count.

20. The semiconductor device of claim 19, wherein the phase generator circuitry comprises:
delay value decoding circuitry configured to receive the update signal and a previous delay value and to generate a delay value based on the update signal and the previous delay value;
unit delay circuitry configured to receive the delay value from the delay value decoding circuitry to be used as the previous delay value for a next cycle; and
strobe generation circuitry configured to receive the delay value and the clock and to add the delay value to the clock to generate the data strobe.
